(19) United States
(12) Patent Application Publication
(10) Pub. No.: US 2025/0386542 A1
(43) Pub. Date: Dec. 18, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Toshifumi NISHIGUCHI, Hakusan Ishikawa (JP); Hiroaki KATOU, Nonoichi Ishikawa (JP); Tsuyoshi KACHI, Kanazawa Ishikawa (JP); Hiroshi HASEGAWA, Nomi Ishikawa (JP); Shuhei TOKUYAMA, Nonoichi Ishikawa (JP)

(21) Appl. No.: 19/036,923

(22) Filed: Jan. 24, 2025

(30) Foreign Application Priority Data
Jun. 18, 2024 (JP) 2024-098263

(51) Int. Cl. H10D 30/66; H10D 64/00; H10D 64/23; H10D 64/27

(52) U.S. Cl. CPC H10D 30/668; H10D 64/117; H10D 64/2527; H10D 64/518; H10D 64/519

(57) ABSTRACT

A semiconductor device of embodiments includes: a first electrode; a second electrode; a semiconductor layer having a first face and a second face; a gate electrode including a second portion and a first portion extending in a first direction in the semiconductor layer; a field plate electrode between the gate electrode and the second face in the semiconductor layer and electrically connected to the first electrode; a conductive layer in the semiconductor layer, provided between the first portion and the second portion, and electrically separated from the first electrode; and a field plate insulating layer between the field plate electrode and the semiconductor layer. A first distance in the first direction between an end of the field plate insulating layer in the first direction on the first face and the conductive layer is smaller than a second distance between the end and the gate electrode in the first direction.

### CROSS-REFERENCE TO RELATED APPLICATION

This application is based upon and claims the benefit of priority from Japanese Patent Application No. 2024-098263, filed on Jun. 18, 2024, the entire contents of which are incorporated herein by reference.

### FIELD

Embodiments described herein relate generally to a semiconductor device.

### BACKGROUND

In order to reduce the size of a transistor or improve the performance of a transistor, a vertical transistor is used in which a gate electrode is buried in a trench. In the vertical transistor, there is a trade-off between the drain-source breakdown voltage (hereinafter, also simply referred to as “breakdown voltage”) and the on-resistance. That is, if the impurity concentration in the drift region is increased in order to reduce the on-resistance, the breakdown voltage decreases. Conversely, if the impurity concentration in the drift region is reduced in order to increase the breakdown voltage, the on-resistance increases.

As a structure to solve the trade-off between the breakdown voltage and the on-resistance, a field plate electrode is provided in the trench of a vertical transistor. By changing the electric field distribution in the drift region using the field plate electrode, it is possible to increase the impurity concentration in the drift region while maintaining the breakdown voltage, for example. Therefore, for example, it is possible to reduce the on-resistance while maintaining the breakdown voltage.

By providing the field plate electrode, a capacitance is added between the gate electrode and the field plate electrode, which may increase the gate capacitance. In order to realize high-speed transistors, it is desirable to reduce the gate capacitance.

### BRIEF DESCRIPTION OF THE DRAWINGS

FIGS. 1A and 1B are schematic diagrams of a semiconductor device according to a first embodiment;

FIG. 2 is a schematic cross-sectional view of a part of the semiconductor device according to the first embodiment;

FIG. 3 is a schematic top view of a part of the semiconductor device according to the first embodiment;

FIG. 4 is a schematic cross-sectional view of a part of the semiconductor device according to the first embodiment;

FIG. 5 is a schematic cross-sectional view of a part of the semiconductor device according to the first embodiment;

FIG. 6 is a schematic cross-sectional view of a part of the semiconductor device according to the first embodiment;

FIG. 7 is a schematic cross-sectional view of a part of the semiconductor device according to the first embodiment;

FIG. 8 is a schematic cross-sectional view of a part of the semiconductor device according to the first embodiment;

FIG. 9 is a schematic cross-sectional view of a part of a semiconductor device according to a first comparative example;

FIG. 10 is a schematic cross-sectional view of a part of a semiconductor device according to a second comparative example;

FIG. 11 is a schematic cross-sectional view of a part of a semiconductor device according to a first modification example of the first embodiment;

FIG. 12 is a schematic cross-sectional view of a part of a semiconductor device according to a second modification example of the first embodiment;

FIG. 13 is a schematic cross-sectional view of a part of a semiconductor device according to a third modification example of the first embodiment;

FIG. 14 is a schematic cross-sectional view of a part of a semiconductor device according to a second embodiment;

FIG. 15 is a schematic top view of a part of the semiconductor device according to the second embodiment;

FIG. 16 is a schematic cross-sectional view of a part of the semiconductor device according to the second embodiment;

FIG. 17 is a schematic cross-sectional view of a part of a semiconductor device according to a first modification example of the second embodiment;

FIG. 18 is a schematic top view of a part of the semiconductor device according to the first modification example of the second embodiment;

FIG. 19 is a schematic cross-sectional view of a part of the semiconductor device according to the first modification example of the second embodiment;

FIG. 20 is a schematic cross-sectional view of a part of the semiconductor device according to the first modification example of the second embodiment;

FIG. 21 is a schematic cross-sectional view of a part of a semiconductor device according to a second modification example of the second embodiment;

FIG. 22 is a schematic top view of a part of the semiconductor device according to the second modification example of the second embodiment;

FIG. 23 is a schematic cross-sectional view of a part of the semiconductor device according to the second modification example of the second embodiment;

FIG. 24 is a schematic cross-sectional view of a part of the semiconductor device according to the second modification example of the second embodiment; and

FIG. 25 is a schematic cross-sectional view of a part of the semiconductor device according to the second modification example of the second embodiment.

### DETAILED DESCRIPTION

A semiconductor device of embodiments includes: a first electrode; a second electrode; a semiconductor layer provided between the first electrode and the second electrode, having a first face facing the first electrode and a second face facing the second electrode, and including a first semiconductor region of a first conductive type electrically connected to the second electrode, a second semiconductor region of a second conductive type provided between the first semiconductor region and the first face, and a third semiconductor region of the first conductive type provided between the second semiconductor region and the first face and electrically connected to the first electrode; a gate electrode including a first portion provided in the semiconductor layer and extending in a first direction parallel to the first face and a second portion disposed in a second direction parallel to the first face and perpendicular to the first direction with respect to the first portion; a field plate electrode provided in the semiconductor layer, provided between the gate electrode and the second face, and electrically connected to the first electrode; a conductive layer provided in the semiconductor layer, provided between the first portion and the second portion, and electrically separated from the first electrode; a gate insulating layer provided between the gate electrode and the semiconductor layer; a field plate insulating layer provided between the field plate electrode and the semiconductor layer; a first insulating layer provided between the conductive layer and the field plate electrode; a second insulating layer provided between the first portion and the conductive layer; and a third insulating layer provided between the second portion and the conductive layer. A first distance in the first direction between an end of the field plate insulating layer in the first direction on the first face and the conductive layer is smaller than a second distance between the end and the gate electrode in the first direction.

Hereinafter, embodiments will be described with reference to the diagrams. In addition, in the following description, the same or similar members and the like are denoted by the same reference numerals, and the description of the members and the like once described will be omitted as appropriate.

In this specification, when there are notations of n⁺-type, n-type, and n⁻-type, this means that the n-type impurity concentration decreases in the order of n⁺-type, n-type, and n⁻-type. In addition, when there are notations of p⁺-type, p-type, and p⁻-type, this means that the p-type impurity concentration decreases in the order of p⁺-type, p-type, and p⁻-type.

The impurity concentration in a semiconductor device can be measured by, for example, secondary ion mass spectrometry (SIMS). In addition, the relative high and low of the impurity concentration in the semiconductor device can be determined from, for example, the high and low of the carrier concentration obtained by scanning capacitance microscopy (SCM). In addition, the distance such as the width or depth of an impurity region in the semiconductor device can be calculated by, for example, SIMS. In addition, the distance such as the width or depth of an impurity region in the semiconductor device can be calculated from, for example, an SCM image.

The qualitative analysis and quantitative analysis of the chemical composition of members forming the semiconductor device in this specification can be performed by, for example, SIMS, energy dispersive X-ray spectroscopy (EDX), and Rutherford back-scattering spectroscopy (RBS). In addition, when measuring the thickness of each member forming the semiconductor device, a distance between members, and the like, for example, a scanning electron microscope (SEM) or a transmission electron microscope (TEM) can be used.

### First Embodiment

A semiconductor device according to a first embodiment includes: a first electrode; a second electrode; a semiconductor layer provided between the first electrode and the second electrode, having a first face facing the first electrode and a second face facing the second electrode, and including a first semiconductor region of a first conductive type electrically connected to the second electrode, a second semiconductor region of a second conductive type provided between the first semiconductor region and the first face, and a third semiconductor region of the first conductive type provided between the second semiconductor region and the first face and electrically connected to the first electrode; a gate electrode including a first portion provided in the semiconductor layer and extending in a first direction parallel to the first face and a second portion disposed in a second direction parallel to the first face and perpendicular to the first direction with respect to the first portion; a field plate electrode provided in the semiconductor layer, provided between the gate electrode and the second face, and electrically connected to the first electrode; a conductive layer provided in the semiconductor layer, provided between the first portion and the second portion, and electrically separated from the first electrode; a gate insulating layer provided between the gate electrode and the semiconductor layer; a field plate insulating layer provided between the field plate electrode and the semiconductor layer; a first insulating layer provided between the conductive layer and the field plate electrode; a second insulating layer provided between the first portion and the conductive layer; and a third insulating layer provided between the second portion and the conductive layer. A first distance in the first direction between an end of the field plate insulating layer in the first direction on the first face and the conductive layer is smaller than a second distance between the end and the gate electrode in the first direction.

Hereinafter, a case where the first conductive type is n-type and the second conductive type is p-type will be described as an example. Hereinafter, a case where the semiconductor device is an n-channel metal oxide semiconductor field effect transistor (MOSFET) having electrons as carriers will be described as an example.

The semiconductor device according to the first embodiment is a MOSFET 100. The MOSFET 100 is a vertical trench gate MOSFET in which a gate electrode and a field plate electrode are provided in a trench.

The trench in this specification is a groove-shaped or concave structure that the semiconductor layer itself has. Therefore, components other than the semiconductor layer can be provided inside the trench. The trench is a part of the semiconductor layer.

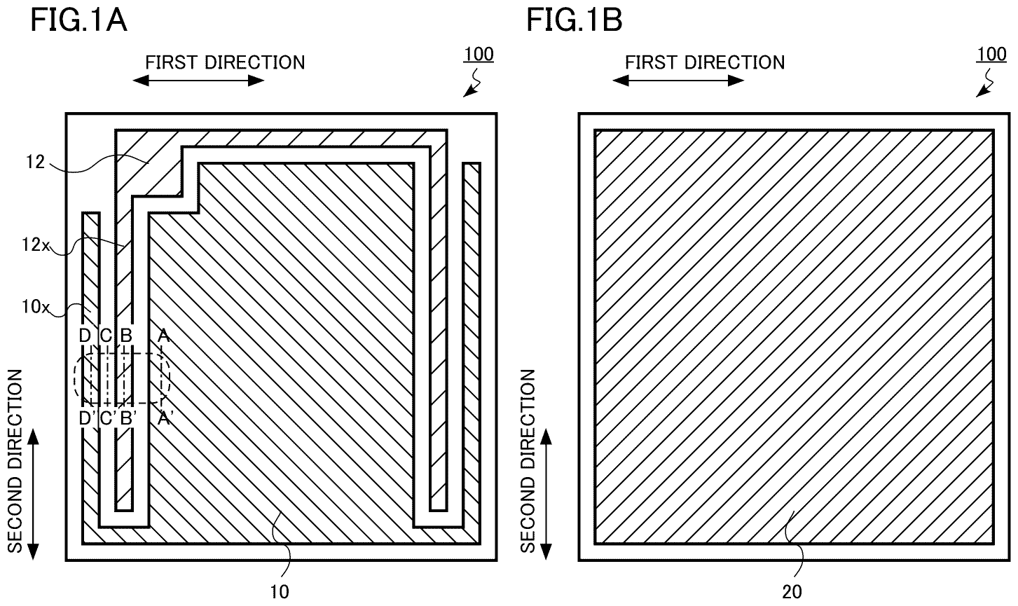

FIGS. 1A and 1B are schematic diagrams of the semiconductor device according to the first embodiment. FIG. 1A is the surface side of the MOSFET 100. FIG. 1B is the back surface side of the MOSFET 100.

As shown in FIG. 1A, a source electrode 10, a source electrode wiring 10x, a gate electrode pad 12, and a gate electrode wiring 12x are provided on the front surface side of the MOSFET 100.

The source electrode wiring 10x is physically and electrically connected to the source electrode 10. The source electrode wiring 10x extends in the second direction.

The gate electrode wiring 12x is physically and electrically connected to the gate electrode pad 12. The gate electrode wiring 12x extends in the second direction. The gate electrode wiring 12x is provided between the source electrode wiring 10x and the source electrode 10 in the first direction.

As shown in FIG. 1B, a drain electrode 20 is provided on the back surface side of the MOSFET 100.

A plurality of transistors are provided below the source electrode 10. The gate electrode pad 12 and the gate electrode wiring 12x are electrically connected to the gate electrode of the transistor. A gate voltage for controlling the switching operation of the transistor is applied to the gate electrode pad 12.

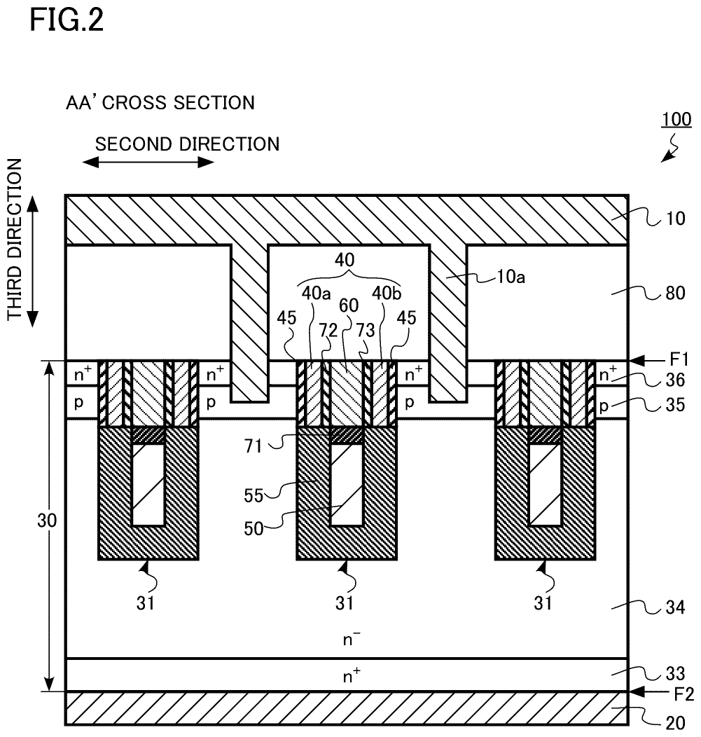

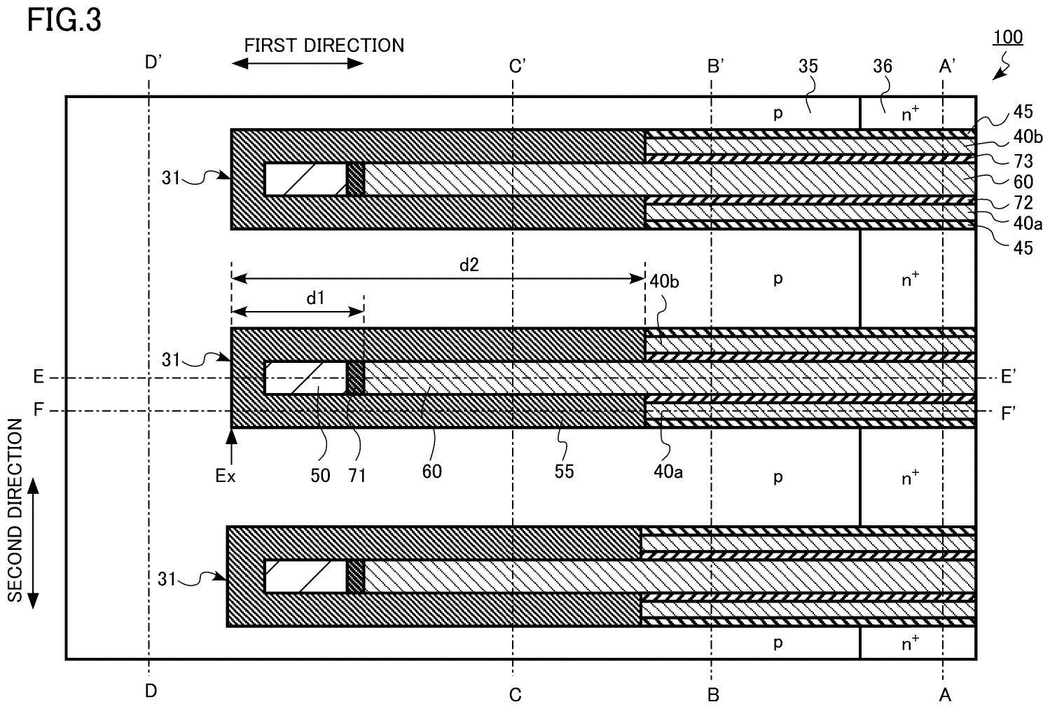

FIG. 2 is a schematic cross-sectional view of a part of the semiconductor device according to the first embodiment. FIG. 2 is a cross-sectional view taken along the line AA′ of FIG. 1A. FIG. 2 is a cross-sectional view taken along the line AA′ of FIG. 3.

FIG. 3 is a schematic top view of a part of the semiconductor device according to the first embodiment. FIG. 3 is a top view of a portion indicated by the dotted line in FIG. 1A. FIG. 3 is a top view including a portion corresponding to FIG. 2. FIG. 3 is a diagram of a position corresponding to a first face F1 of a semiconductor layer 30. FIG. 3 is a diagram excluding components above the first face F1.

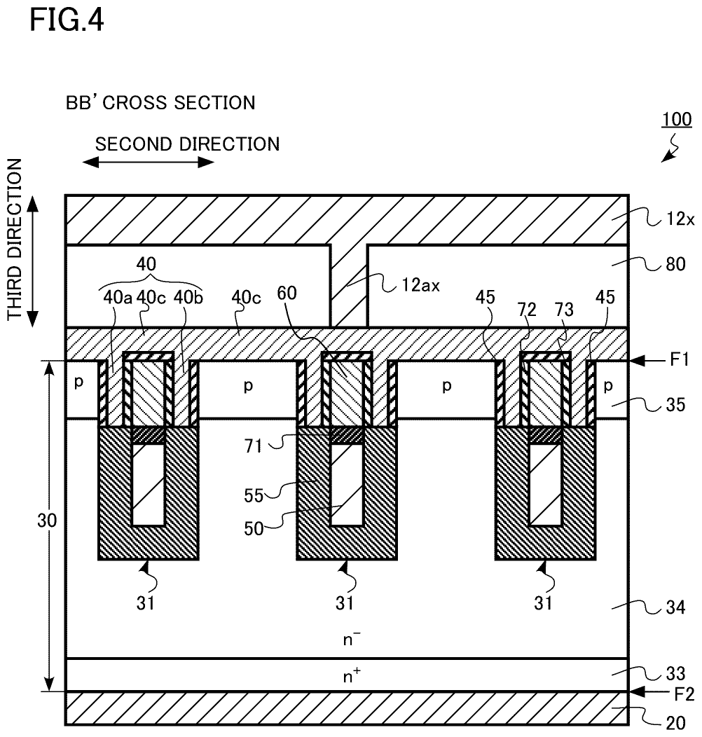

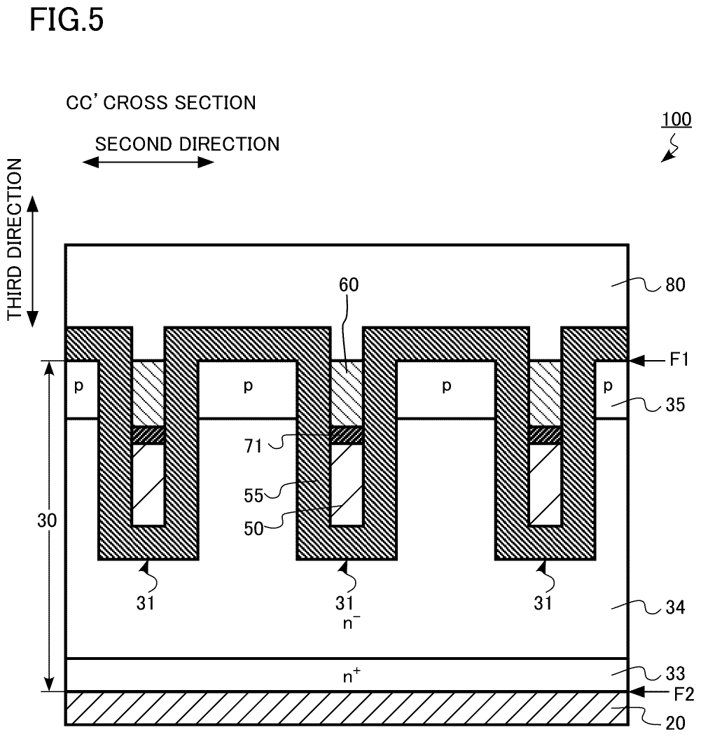

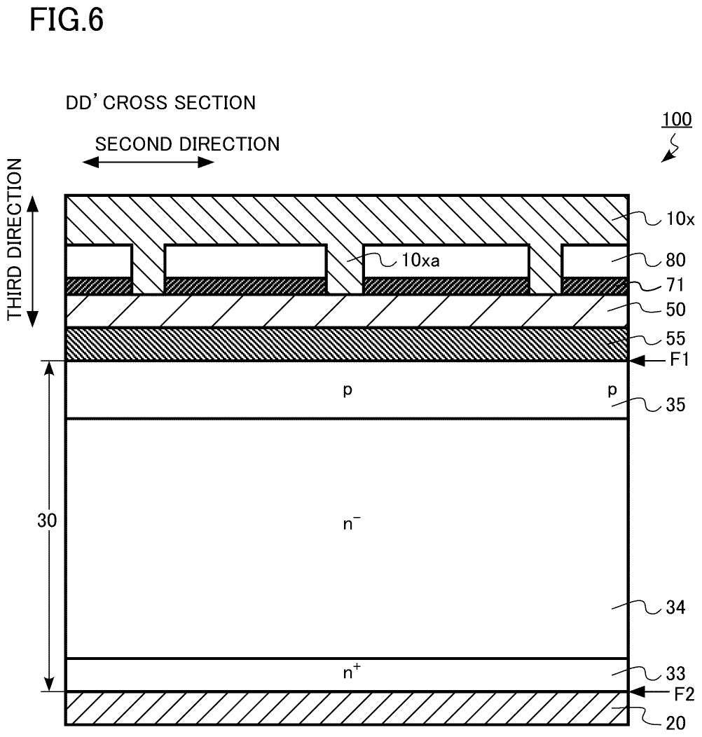

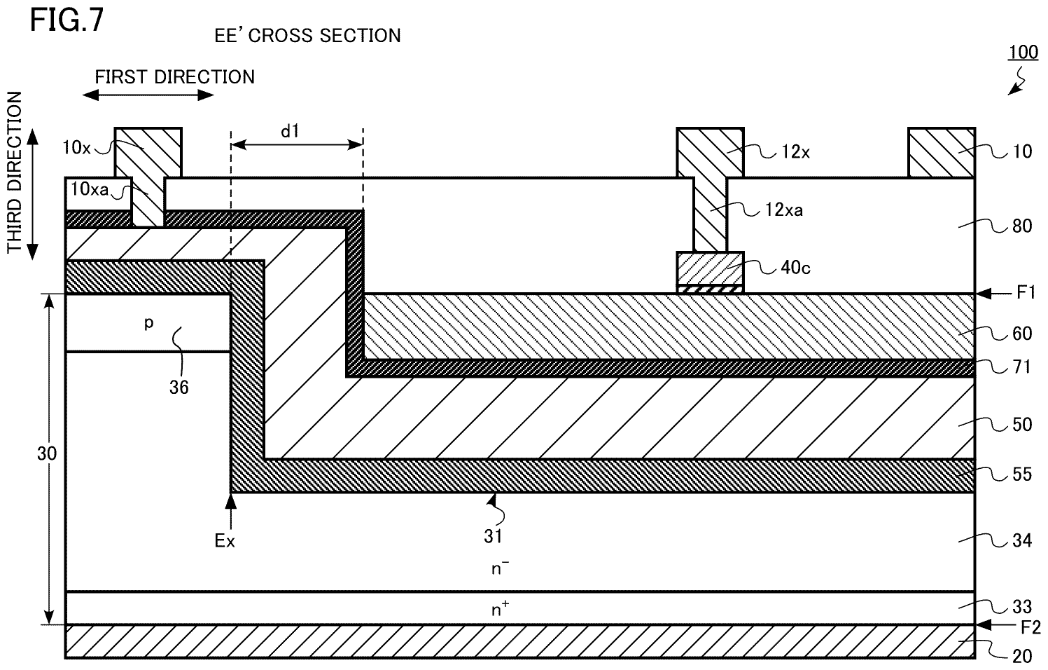

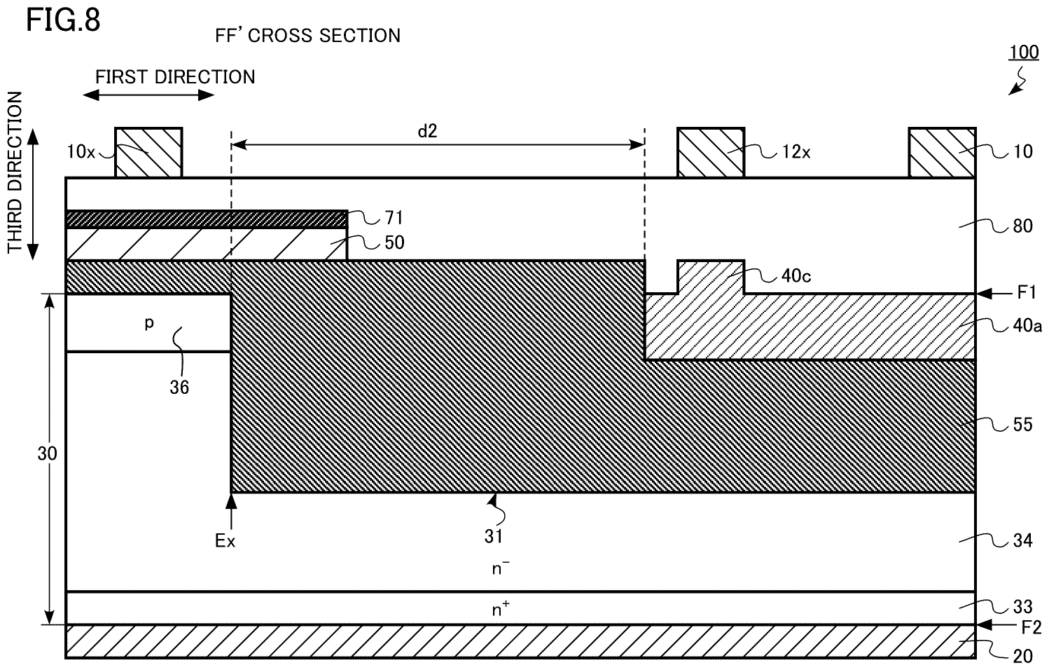

FIGS. 4, 5, 6, 7, and 8 are schematic cross-sectional views of a part of the semiconductor device according to the first embodiment. FIG. 4 is a cross-sectional view taken along the line BB′ of FIGS. 1A and 3. FIG. 5 is a cross-sectional view taken along the line CC′ of FIGS. 1A and 3. FIG. 6 is a cross-sectional view taken along the line DD′ of FIGS. 1A and 3. FIG. 7 is a cross-sectional view taken along the line EE′ of FIG. 3. FIG. 8 is a cross-sectional view taken along the line FF′ of FIG. 3.

The MOSFET 100 includes the source electrode 10 (first electrode), the drain electrode 20 (second electrode), the semiconductor layer 30, a gate electrode 40, a gate insulating layer 45, a field plate electrode 50, a field plate insulating layer 55, a conductive layer 60, a first interelectrode insulating layer 71 (first insulating layer), a second interelectrode insulating layer 72 (second insulating layer), a third interelectrode insulating layer 73 (third insulating layer), and an interlayer insulating layer 80.

The source electrode 10 includes a source contact plug 10a. The source electrode wiring 10x includes a field plate contact plug 10xa. The gate electrode wiring 12x includes a gate contact plug 12xa.

The semiconductor layer 30 includes a trench 31, an n⁺-type drain region 33, an n⁻-type drift region 34 (first semiconductor region), a p-type body region 35 (second semiconductor region), and an n⁺-type source region 36 (third semiconductor region).

The gate electrode 40 includes a first portion 40a, a second portion 40b, and a third portion 40c.

The semiconductor layer 30 is provided between the source electrode 10 and the drain electrode 20. The semiconductor layer 30 includes a first face (“F1” in FIG. 2) and a second face (“F2” in FIG. 2). The second face F2 is opposite to the first face F1.

The first face F1 faces source electrode 10. The second face F2 faces the drain electrode 20.

The first direction and the second direction are directions parallel to the first face F1. The second direction is a direction perpendicular to the first direction. In addition, the third direction is a direction perpendicular to the first face F1. The third direction is a direction perpendicular to the first direction and the second direction.

Hereinafter, “depth” means a depth with respect to the first face F1. That is, “depth” means a distance in the third direction with respect to the first face F1.

The semiconductor layer 30 is, for example, single crystal silicon (Si). When the semiconductor layer 30 is formed of single crystal silicon, the surface of the semiconductor layer 30 is a face inclined at an angle equal to or more than 0° and equal to or less than 8° with respect to the (100)-face, for example.

The n⁺-type drain region 33 is provided in the semiconductor layer 30. The drain region 33 is in contact with the second face F2. The drain region 33 is in contact with the drain electrode 20. The drain region 33 is electrically connected to the drain electrode 20.

The drain region 33 contains n-type impurities. The n-type impurity is, for example, phosphorus (P) or arsenic (As). The n-type impurity concentration is equal to or more than 1×10¹⁸ cm⁻³ and equal to or less than 1×10²¹ cm⁻³, for example.

The n⁻-type drift region 34 is provided in the semiconductor layer 30. The drift region 34 is provided between the drain region 33 and the first face F1. The drift region 34 is provided on the drain region 33. The drift region 34 functions as a current path when the MOSFET 100 is turned on.

The drift region 34 contains n-type impurities. The n-type impurity is, for example, phosphorus (P) or arsenic (As). The n-type impurity concentration is, for example, equal to or more than 1×10¹⁵ cm⁻³ and equal to or less than 1×10¹⁸ cm⁻³.

The thickness of the drift region 34 in the third direction is, for example, equal to or more than 5 μm and equal to or less than 15 μm.

The p-type body region 35 is provided in the semiconductor layer 30. The body region 35 is provided between the drift region 34 and the first face F1.

The body region 35 is provided between two adjacent trenches 31.

The body region 35 is in contact with, for example, the source electrode 10. The body region 35 is electrically connected to, for example, the source electrode 10. For example, as shown in FIG. 2, the body region 35 is electrically connected to the source electrode 10 using the source contact plug 10a. The source contact plug 10a is in contact with the body region 35.

When the MOSFET 100 is turned on, a channel of an inversion layer is formed in the body region 35 facing the gate electrode 40.

The body region 35 contains p-type impurities. The p-type impurity is, for example, boron (B). The p-type impurity concentration is, for example, equal to or more than 1×10¹⁶ cm⁻³ and equal to or less than 1×10²⁰ cm⁻³.

The n⁺-type source region 36 is provided in the semiconductor layer 30. The source region 36 is provided between the body region 35 and the first face F1.

The source region 36 is in contact with the first face F1. The source region 36 is in contact with the source electrode 10. The source region 36 is electrically connected to the source electrode 10. For example, as shown in FIG. 2, the source region 36 is electrically connected to the source electrode 10 using the source contact plug 10a. The source contact plug 10a is in contact with the source electrode 10.

The source region 36 is provided between two adjacent trenches 31.

The source region 36 contains n-type impurities. The n-type impurity is, for example, phosphorus (P) or arsenic (As). The n-type impurity concentration is, for example, equal to or more than 1×10¹⁹ cm⁻³ and equal to or less than 1×10²¹ cm⁻³.

The trench 31 is provided in the semiconductor layer 30. The trench 31 is disposed on the first face F1 side of the semiconductor layer 30. The trench 31 is a groove formed in the semiconductor layer 30.

As shown in FIG. 3, the trench 31 extends in the first direction. A plurality of trenches 31 are repeatedly arranged in the second direction. For example, a plurality of trenches 31 are repeatedly arranged at predetermined pitches in the second direction.

The trench 31 penetrates the body region 35 and reaches the drift region 34. The depth of the trench 31 is, for example, equal to or more than 1 μm and equal to or less than 5 μm. The width of the trench 31 in the second direction is, for example, equal to or more than 0.3 μm and equal to or less than 1 μm.

The gate electrode 40 is provided in the semiconductor layer 30. The gate electrode 40 is provided between a part of the semiconductor layer 30 and another part of the semiconductor layer 30. The gate electrode 40 is provided in the trench 31. The gate electrode 40 includes the first portion 40a, the second portion 40b, and the third portion 40c.

As shown in FIG. 2, the second portion 40b is disposed in the second direction with respect to the first portion 40a. The second portion 40b is spaced from the first portion 40a in the second direction within the trench 31.

As shown in FIG. 4, the third portion 40c connects the first portion 40a and the second portion 40b to each other. The third portion 40c extends in the second direction.

For example, as shown in FIG. 4, the gate electrode 40 is electrically connected to the gate electrode wiring 12x using the gate contact plug 12xa. The gate contact plug 12xa is in contact with the third portion 40c.

The gate electrode 40 is a conductor. The gate electrode 40 is, for example, polycrystalline silicon containing n-type or p-type impurities.

The gate insulating layer 45 is provided between the gate electrode 40 and the semiconductor layer 30. The gate insulating layer 45 is provided between the gate electrode 40 and the body region 35. The gate insulating layer 45 is provided between the gate electrode 40 and the drift region 34. The gate insulating layer 45 is provided between the gate electrode 40 and the source region 36. The gate insulating layer 45 is, for example, a silicon oxide.

The field plate electrode 50 is provided in the semiconductor layer 30. The field plate electrode 50 is provided between a part of the semiconductor layer 30 and another part of the semiconductor layer 30. The field plate electrode 50 is provided in the trench 31. The field plate electrode 50 is provided between the gate electrode 40 and the second face F2. The distance between the second face F2 and the field plate electrode 50 in the third direction is smaller than the distance between the second face F2 and the gate electrode 40 in the third direction. The field plate electrode 50 extends in the first direction.

The field plate electrode 50 has a function of changing the electric field distribution in the drift region 34 when the MOSFET 100 is turned off, thereby increasing the breakdown voltage of the MOSFET 100.

For example, as shown in FIG. 6, the field plate electrode 50 is electrically connected to the source electrode wiring 10x using the field plate contact plug 10xa. The field plate electrode 50 is electrically connected to the source electrode 10. The field plate contact plug 10xa is in contact with the field plate electrode 50. The field plate electrode 50 is connected to the source electrode wiring 10x, for example, in a region directly below which there is no trench.

The field plate electrode 50 is a conductor. The field plate electrode 50 is, for example, polycrystalline silicon containing n-type or p-type impurities.

The field plate insulating layer 55 is provided between the field plate electrode 50 and the semiconductor layer 30. The field plate insulating layer 55 is provided between the field plate electrode 50 and the drift region 34. The field plate insulating layer 55 is, for example, a silicon oxide.

The thickness of the field plate insulating layer 55 in the second direction is, for example, larger than the thickness of the gate insulating layer 45 in the second direction. The thickness of the field plate insulating layer 55 in the second direction is, for example, equal to or more than 3 times and equal to or less than 30 times the thickness of the gate insulating layer 45 in the second direction.

The conductive layer 60 is provided in the semiconductor layer 30. The conductive layer 60 is provided between a part of the semiconductor layer 30 and another part of the semiconductor layer 30. The conductive layer 60 is provided in the trench 31. The conductive layer 60 is provided between the first portion 40a and the second portion 40b of the gate electrode 40. The conductive layer 60 is spaced from the gate electrode 40. The conductive layer 60 is spaced from the field plate electrode 50. The field plate electrode 50 is provided between the conductive layer 60 and the second face F2. The conductive layer 60 is electrically separated from the source electrode 10. The conductive layer 60 is electrically separated from the gate electrode 40. In addition, being electrically separated means a state in which there is no electrical short circuit (short).

The conductive layer 60 is floating. The conductive layer 60 is not fixed to any potential.

The first interelectrode insulating layer 71 is provided between the conductive layer 60 and the field plate electrode 50. For example, the first interelectrode insulating layer 71 is provided between the gate electrode 40 and the field plate electrode 50. The first interelectrode insulating layer 71 is, for example, a silicon oxide.

The thickness of the first interelectrode insulating layer 71 between the conductive layer 60 and the field plate electrode 50 in the third direction is, for example, larger than the thickness of the gate insulating layer 45 in the second direction. The thickness of the first interelectrode insulating layer 71 between the conductive layer 60 and the field plate electrode 50 in the third direction is, for example, equal to or more than twice and equal to or less than five times the thickness of the gate insulating layer 45 in the second direction.

The second interelectrode insulating layer 72 is provided between the first portion 40a of the gate electrode 40 and the conductive layer 60. The second interelectrode insulating layer 72 is, for example, a silicon oxide.

The third interelectrode insulating layer 73 is provided between the second portion 40b of the gate electrode 40 and the conductive layer 60. The third interelectrode insulating layer 73 is, for example, a silicon oxide.

The interlayer insulating layer 80 is provided between the gate electrode 40 and the source electrode 10. The interlayer insulating layer 80 has a function of electrically separating the gate electrode 40 and the source electrode 10 from each other. The interlayer insulating layer 80 is, for example, a silicon oxide.

The source electrode 10 is provided on the first face F1 side of the semiconductor layer 30. The source electrode 10 is provided above the first face F1 of the semiconductor layer 30.

The source electrode 10 is electrically connected to the source region 36 and the body region 35. The source electrode 10 is in contact with, for example, the source region 36 and the body region 35.

The source electrode 10 is a region to which, for example, a bonding wire is connected when the MOSFET 100 is mounted.

The source electrode 10 is a metal. The source electrode 10 has a stacked structure of, for example, titanium (Ti) and aluminum (Al).

The source electrode wiring 10x is physically and electrically connected to the source electrode 10. The source electrode 10 and the field plate electrode 50 are electrically connected to each other using the source electrode wiring 10x.

The source electrode wiring 10x is a metal. The source electrode wiring 10x has a stacked structure of, for example, titanium (Ti) and aluminum (Al). The material of the source electrode wiring 10x is the same as the material of the source electrode 10, for example.

The drain electrode 20 is provided on the second face F2 side of the semiconductor layer 30. The drain electrode 20 is provided on the second face F2 of the semiconductor layer 30. The drain electrode 20 is electrically connected to the drain region 33. The drain electrode 20 is in contact with the drain region 33.

The drain electrode 20 is a metal. The drain electrode 20 has a stacked structure of materials selected from, for example, titanium (Ti), aluminum (Al), nickel (Ni), copper (Cu), silver (Ag), and gold (Au).

The gate electrode pad 12 is provided on the first face F1 side of the semiconductor layer 30. The gate electrode pad 12 is provided above the first face F1 of the semiconductor layer 30.

The gate electrode pad 12 is electrically connected to the gate electrode 40. The gate electrode pad 12 is a region to which, for example, a bonding wire is connected when the MOSFET 100 is mounted.

The gate electrode pad 12 is a metal. The gate electrode pad 12 has a stacked structure of, for example, titanium (Ti) and aluminum (Al). The material of the gate electrode pad 12 is the same as the material of the source electrode 10, for example.

The gate electrode wiring 12x is physically and electrically connected to the gate electrode 40. The gate electrode pad 12 and the gate electrode 40 are electrically connected to each other using the gate electrode wiring 12x.

The gate electrode wiring 12x is a metal. The gate electrode wiring 12x has a stacked structure of, for example, titanium (Ti) and aluminum (Al). The material of the gate electrode wiring 12x is the same as the material of the source electrode 10 and the material of the gate electrode pad 12, for example.

As shown in FIGS. 3 and 7, the distance in the first direction between the conductive layer 60 and the end (Ex in FIGS. 3 and 7) of the first face F1 of the field plate insulating layer 55 in the first direction is a first distance d1. In other words, the distance in the first direction between the conductive layer 60 and the end (Ex in FIGS. 3 and 7) of the trench 31 in the first direction is the first distance d1. In addition, as shown in FIGS. 3 and 8, the distance in the first direction between the gate electrode 40 and the end (Ex in FIGS. 3 and 7) of the first face F1 of the field plate insulating layer 55 in the first direction is a second distance d2. In other words, the distance in the first direction between the gate electrode 40 and the end (Ex in FIGS. 3 and 8) of the trench 31 in the first direction is the second distance d2.

The first distance d1 is smaller than the second distance d2. In other words, the second distance d2 is larger than the first distance d1.

The difference between the second distance d2 and the first distance d1 is, for example, larger than the depth of the field plate insulating layer 55 in the third direction. The difference between the second distance d2 and the first distance d1 is, for example, equal to or less than 50 times the depth of the field plate insulating layer 55 in the third direction. The difference between the second distance d2 and the first distance d1 is, for example, equal to or more than 10 μm and equal to or less than 100 μm.

The difference between the second distance d2 and the first distance d1 is, for example, larger than the depth of the trench 31 in the third direction. The difference between the second distance d2 and the first distance d1 is, for example, equal to or less than 50 times the depth of the trench 31 in the third direction. The difference between the second distance d2 and the first distance d1 is, for example, equal to or more than 10 μm and equal to or less than 100 μm.

The structure inside the trench 31 of the MOSFET 100 according to the first embodiment is manufactured by repeating the formation of an insulating film and the burying of a conductive film in the trench 31. When removing the conductive film or the insulating film, a mask material is used. By appropriately determining the position of the end of the mask material in the vicinity of the end Ex of the trench 31 in the first direction, it is possible to make the first distance d1 smaller than the second distance d2.

For example, the position of the end of a first mask material when etching a conductive film that forms the field plate electrode 50 is defined as a first position. The position of the end of the conductive layer 60 in the first direction is dominated by the first position. In addition, the position of the end of a second mask material when etching an insulator film that becomes the field plate insulating layer 55 after the conductive layer 60 is formed is defined as a second position. The position of the end of the gate electrode 40 in the first direction is dominated by the second position. By making the first position closer to the end Ex of the trench 31 in the first direction than the second position, it is possible to make the first distance d1 smaller than the second distance d2.

Next, the function and effect of the semiconductor device according to the first embodiment will be described.

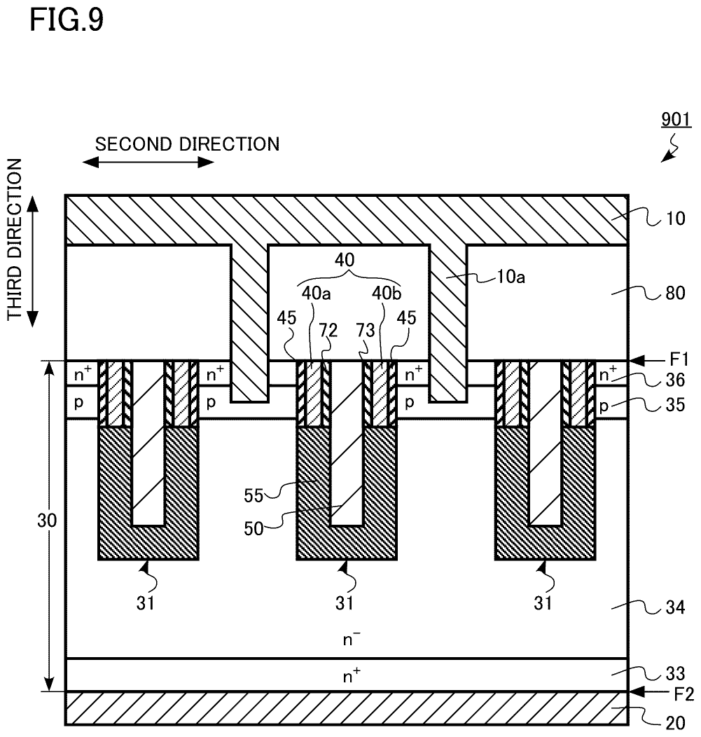

FIG. 9 is a schematic cross-sectional view of a part of a semiconductor device according to a first comparative example. FIG. 9 is a diagram corresponding to FIG. 2 in the first embodiment.

The semiconductor device according to the first comparative example is a MOSFET 901. The MOSFET 901 is different from the MOSFET 100 according to the first embodiment in that the conductive layer 60 is not provided and the field plate electrode 50 is provided between the first portion 40a and the second portion 40b of the gate electrode 40.

In the MOSFET 901 according to the first comparative example, the gate electrode 40 faces the field plate electrode 50 electrically connected to the source electrode 10 in the second direction. The capacitance between the gate electrode 40 and the field plate electrode 50 facing each other in the second direction is a gate-source capacitance.

In the MOSFET 901 according to the first comparative example, there is a concern that the gate-source capacitance increases to hinder an increase in the speed of the transistor.

In the MOSFET 100 according to the first embodiment, the gate electrode 40 faces the conductive layer 60 in the second direction. The conductive layer 60 is floating because the conductive layer 60 is not electrically connected to the source electrode 10. Therefore, the MOSFET 100 has a reduced gate-source capacitance as compared to the MOSFET 901 according to the first comparative example. As a result, since the gate capacitance of the MOSFET 100 is reduced, the speed of the MOSFET 100 can be increased.

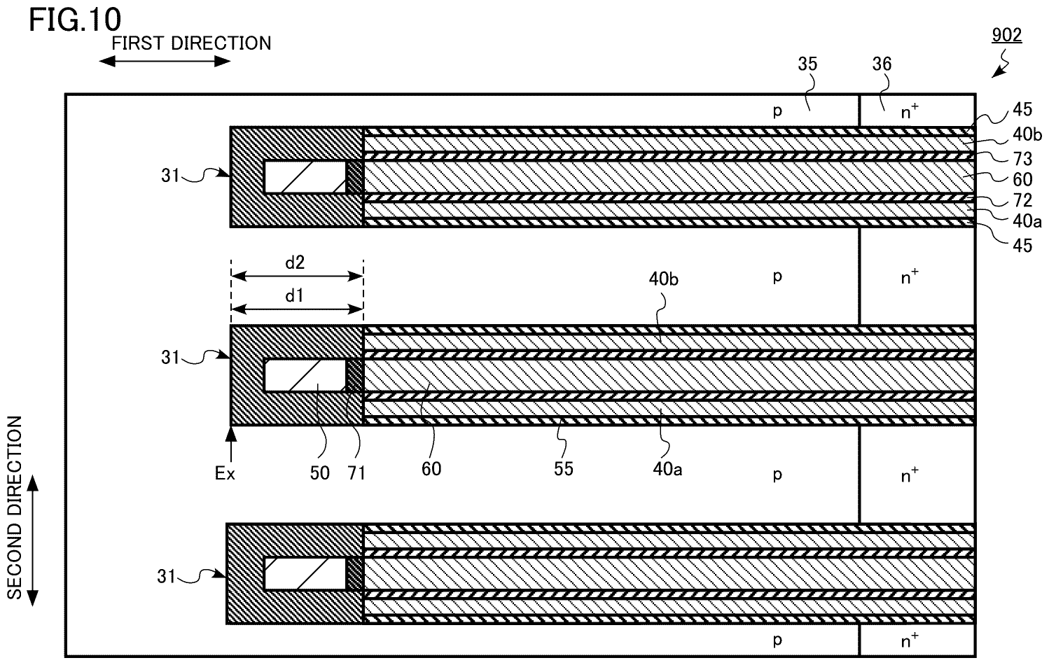

FIG. 10 is a schematic cross-sectional view of a part of a semiconductor device according to a second comparative example. FIG. 10 is a diagram corresponding to FIG. 3 in the first embodiment.

The semiconductor device according to the second comparative example is a MOSFET 902. The MOSFET 902 is different from the MOSFET 100 according to the first embodiment in that the first distance d1 is equal to the second distance d2 as shown in FIG. 10.

In the MOSFET 902, the gate electrode 40 is adjacent to the field plate electrode 50 electrically connected to the source electrode 10 in the vicinity of the end Ex of the trench 31 in the first direction. The capacitance between the gate electrode 40 and the field plate electrode 50 is a gate-source capacitance.

In the MOSFET 902 according to the second comparative example, there is a concern that the gate-source capacitance increases to hinder an increase in the speed of the transistor.

In the MOSFET 100 according to the first embodiment, the first distance d1 is smaller than the second distance d2, in other words, the second distance d2 is larger than the first distance d1. Therefore, in the MOSFET 100, in the vicinity of the end Ex of the trench 31 in the first direction, the distance between the gate electrode 40 and the field plate electrode 50 in a plane parallel to the first face is larger than that in the MOSFET 902 according to the second comparative example. Therefore, the MOSFET 100 has a reduced gate-source capacitance as compared to the MOSFET 902 according to the second comparative example. As a result, since the gate capacitance of the MOSFET 100 is reduced, the speed of the MOSFET 100 can be increased.

As described above, according to the MOSFET 100 of the first embodiment, since the gate capacitance is reduced, it is possible to increase the speed of the MOSFET.

From the viewpoint of reducing the gate-source capacitance, the difference between the second distance d2 and the first distance d1 is preferably larger than the depth of the field plate insulating layer 55, more preferably equal to or more than twice the depth of the field plate insulating layer 55, and even more preferably equal to or more than five times the depth of the field plate insulating layer 55.

From the viewpoint of reducing the gate-source capacitance, the difference between the second distance d2 and the first distance d1 is preferably larger than the depth of the trench 31, more preferably equal to or more than twice the depth of the trench 31, and even more preferably equal to or more than five times the depth of the trench 31.

From the viewpoint of reducing the gate-source capacitance, the difference between the second distance d2 and the first distance d1 is preferably equal to or more than 10 μm, more preferably equal to or more than 20 μm, and even more preferably equal to or more than 30 μm.

From the viewpoint of suppressing the conductive layer 60 from being fixed to the source potential due to coupling with the field plate electrode 50, it is preferable that the thickness of the first interelectrode insulating layer 71 between the conductive layer 60 and the field plate electrode 50 in the third direction is larger than the thickness of the gate insulating layer 45 in the second direction. The thickness of the first interelectrode insulating layer 71 between the conductive layer 60 and the field plate electrode 50 in the third direction is preferably equal to or more than twice the thickness of the gate insulating layer 45 in the second direction, more preferably equal to or more than three times the thickness of the gate insulating layer 45 in the second direction.

### First Modification Example

A semiconductor device according to a first modification example of the first embodiment is different from the semiconductor device according to the first embodiment in that, at the end of the conductive layer in the first direction, the angle between the interface between the conductive layer and the first insulating layer and the first face is equal to or less than 60°.

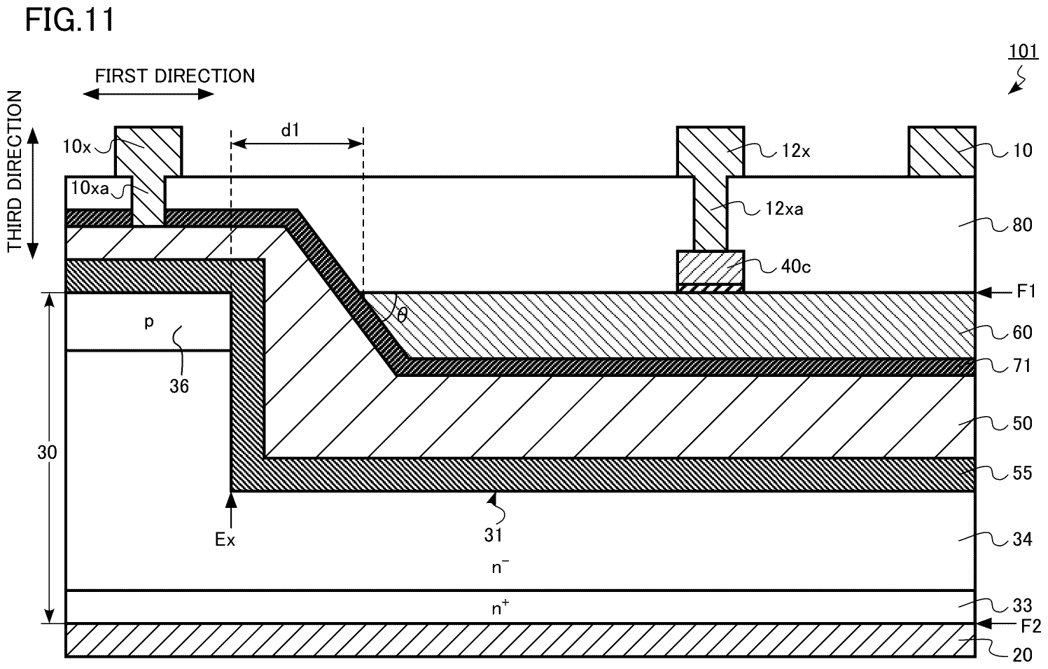

FIG. 11 is a schematic cross-sectional view of a part of the semiconductor device according to the first modification example of the first embodiment. FIG. 11 is a diagram corresponding to FIG. 7 in the first embodiment.

The semiconductor device according to the first modification example of the first embodiment is a MOSFET 101. As shown in FIG. 11, in the MOSFET 101, at the end of the conductive layer 60 in the first direction, the angle (θ in FIG. 11) between the interface between the conductive layer 60 and the first interelectrode insulating layer 71 and the first face F1 is equal to or less than 60°. The angle θ between the interface between the conductive layer 60 and the first interelectrode insulating layer 71 and the first face F1 is, for example, equal to or more than 20° and equal to or less than 60°.

According to the MOSFET 101 of the first modification example of the first embodiment, since the gate capacitance is reduced, the speed of the MOSFET can be increased, as in the first embodiment. In addition, in the MOSFET 101 according to the first modification example of the first embodiment, when forming the first interelectrode insulating layer 71 using a vapor phase growth method, the inclination of the base is gentle, which improves, for example, the uniformity of the film thickness of the first interelectrode insulating layer 71.

### Second Modification Example

A semiconductor device according to a second modification example of the first embodiment is different from the semiconductor device according to the first embodiment in that the gate electrode does not include the third portion.

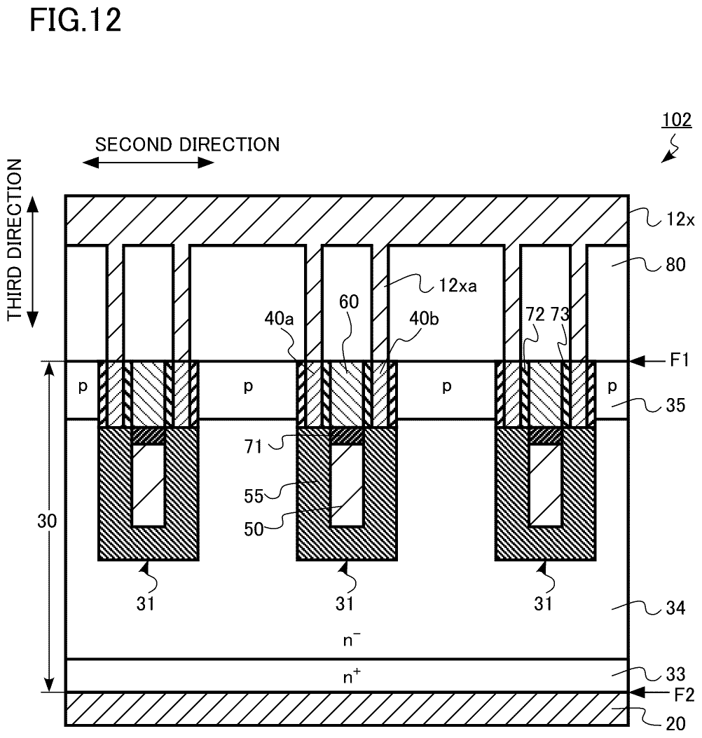

FIG. 12 is a schematic cross-sectional view of a part of the semiconductor device according to the second modification example of the first embodiment. FIG. 12 is a diagram corresponding to FIG. 4 in the first embodiment.

The semiconductor device according to the second modification example of the first embodiment is a MOSFET 102. In the MOSFET 102, as shown in FIG. 12, the gate electrode 40 does not include the third portion 40c. The gate contact plug 12xa is directly connected to the first portion 40a and the second portion 40b as shown in FIG. 12. The gate contact plug 12xa is in contact with the first portion 40a and the second portion 40b.

According to the MOSFET 102 of the second modification example of the first embodiment, since the gate capacitance is reduced, the speed of the MOSFET can be increased, as in the first embodiment.

### Third Modification Example

A semiconductor device according to a third modification example of the first embodiment is different from the semiconductor device according to the first embodiment in that the conductive layer is electrically connected to the gate electrode.

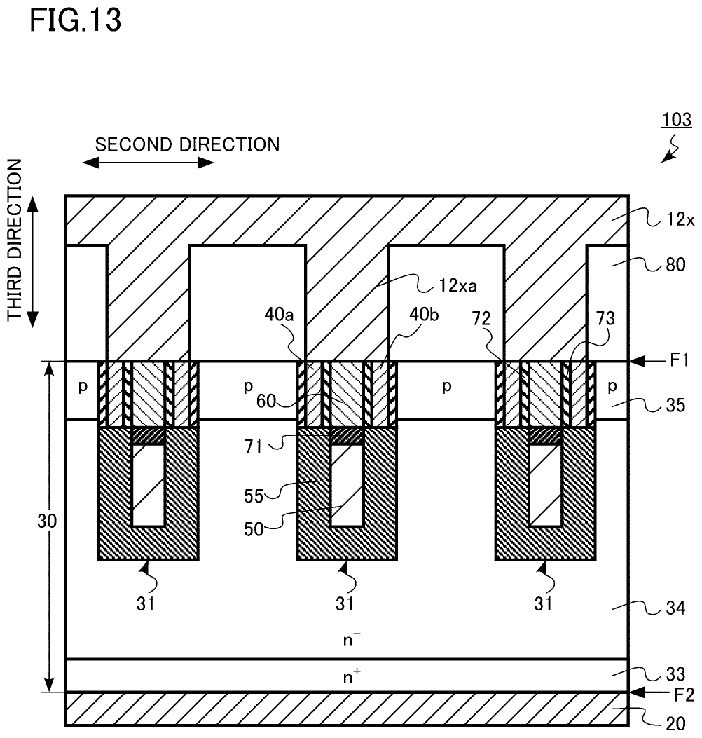

FIG. 13 is a schematic cross-sectional view of a part of the semiconductor device according to the third modification example of the first embodiment. FIG. 13 is a diagram corresponding to FIG. 4 in the first embodiment.

The semiconductor device according to the third modification example of the first embodiment is a MOSFET 103. In the MOSFET 103, as shown in FIG. 13, the gate contact plug 12xa is directly connected to the conductive layer 60 in addition to the first portion 40a and the second portion 40b. The conductive layer 60 is electrically connected to the gate electrode 40 by being electrically connected to the gate electrode wiring 12x.

Since the gate electrode 40 and the conductive layer 60 have the same potential, the capacitance between the gate electrode 40 and the conductive layer 60 does not become a gate capacitance even if the gate electrode 40 and the conductive layer 60 face each other in the second direction. Therefore, the increase in the gate capacitance is suppressed.

In the MOSFET 103 as well, similarly to the MOSFET 100 according to the first embodiment, the second distance d2 is larger than the first distance d1. Therefore, in the vicinity of the end Ex of the trench 31 in the first direction, the distance between the gate electrode 40 and the field plate electrode 50 in a plane parallel to the first face increases. Therefore, in the MOSFET 103 as well, the gate-source capacitance is reduced, similarly to the MOSFET 100 according to the first embodiment. As a result, since the gate capacitance of the MOSFET 103 is reduced, the speed of the MOSFET 103 can be increased.

In the MOSFET 103, since the conductive layer 60 has the same potential as the gate electrode 40, the capacitance between the conductive layer 60 and the field plate electrode 50 becomes the gate-source capacitance. The gate-source capacitance of the MOSFET 103 can be reduced, for example, by increasing the thickness of the first interelectrode insulating layer 71.

According to the MOSFET 103 of the third modification example of the first embodiment, since the gate capacitance is reduced, the speed of the MOSFET can be increased, as in the first embodiment.

As described above, according to the first embodiment and its modification examples, it is possible to realize a semiconductor device with a reduced gate capacitance.

### Second Embodiment

A semiconductor device according to a second embodiment is different from the semiconductor device according to the first embodiment in that the field plate electrode is electrically connected to the source electrode wiring on the conductive layer side of the end of the field plate insulating layer in the first direction on the first face. Hereinafter, the description of the content overlapping the first embodiment may be omitted.

The semiconductor device according to the second embodiment is a MOSFET 200. The MOSFET 200 is a vertical trench gate MOSFET in which a gate electrode and a field plate electrode are provided in a trench.

Similarly to the MOSFET 100 according to the first embodiment, a source electrode 10, a source electrode wiring 10x, a gate electrode pad 12, and a gate electrode wiring 12x are provided on the surface side of the MOSFET 200.

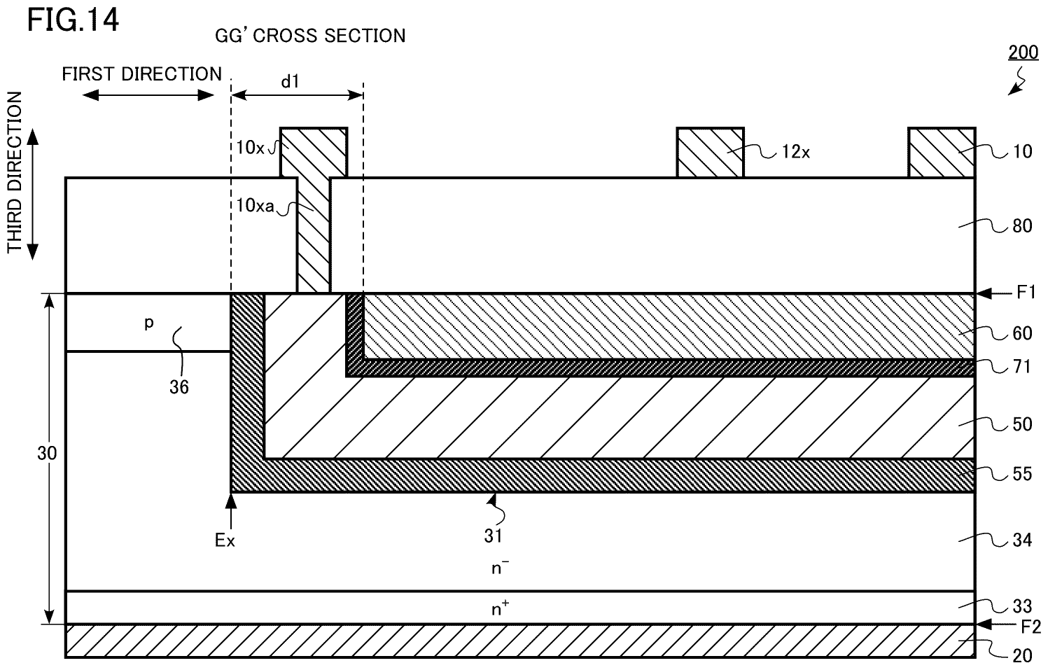

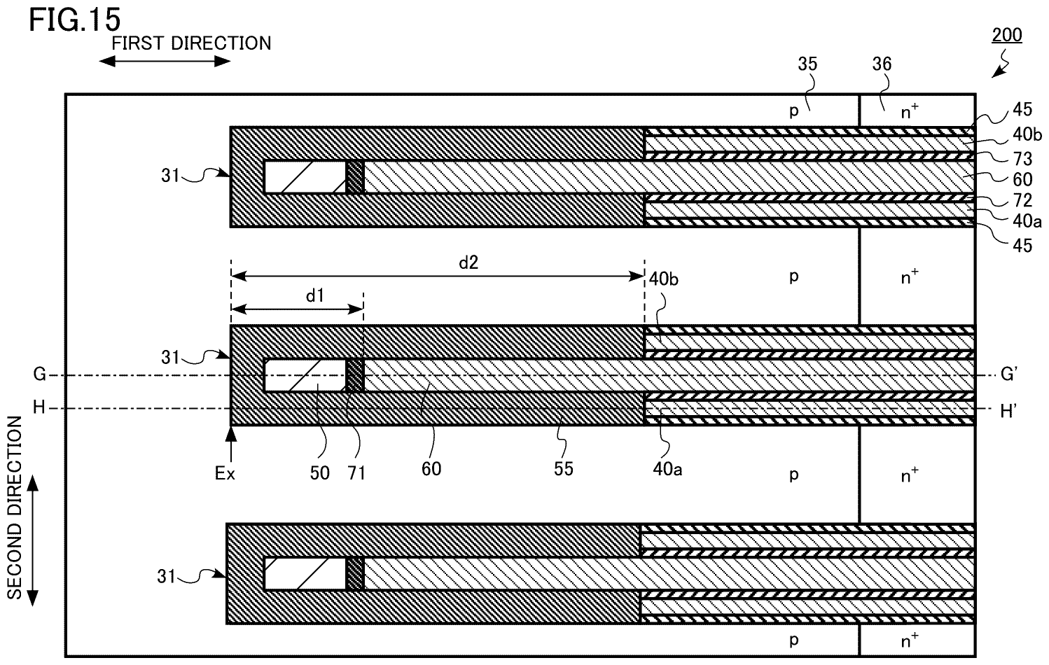

FIG. 14 is a schematic cross-sectional view of a part of the semiconductor device according to the second embodiment. FIG. 14 is a cross-sectional view taken along the line GG′ of FIG. 15. FIG. 14 is a diagram corresponding to FIG. 7 in the first embodiment.

FIG. 15 is a schematic top view of a part of the semiconductor device according to the second embodiment. FIG. 15 is a diagram corresponding to FIG. 3 in the first embodiment.

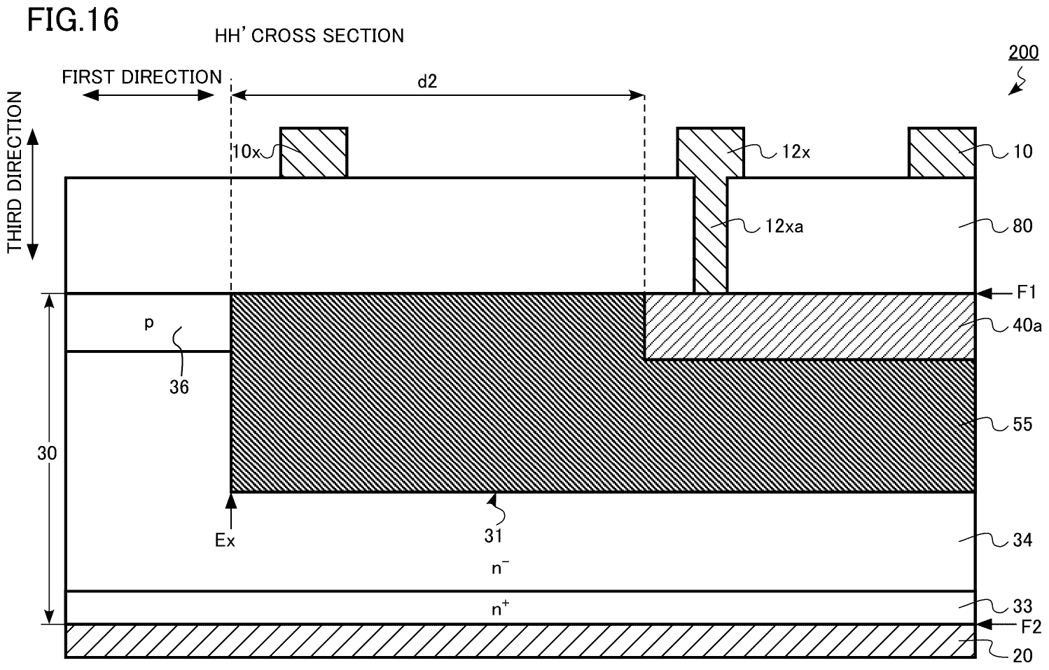

FIG. 16 is a schematic cross-sectional view of a part of the semiconductor device according to the second embodiment. FIG. 16 is a cross-sectional view taken along the line HH′ of FIG. 15. FIG. 16 is a diagram corresponding to FIG. 8 in the first embodiment.

The MOSFET 200 includes the source electrode 10 (first electrode), a drain electrode 20 (second electrode), a semiconductor layer 30, a gate electrode 40, a gate insulating layer 45, a field plate electrode 50, a field plate insulating layer 55, a conductive layer 60, a first interelectrode insulating layer 71 (first insulating layer), a second interelectrode insulating layer 72 (second insulating layer), a third interelectrode insulating layer 73 (third insulating layer), and an interlayer insulating layer 80.

The source electrode 10 includes a source contact plug 10a. The source electrode wiring 10x includes a field plate contact plug 10xa. The gate electrode wiring 12x includes a gate contact plug 12xa.

The semiconductor layer 30 includes a trench 31, an n⁺-type drain region 33, an n⁻-type drift region 34 (first semiconductor region), a p-type body region 35 (second semiconductor region), and an n⁺-type source region 36 (third semiconductor region).

The gate electrode 40 includes a first portion 40a and a second portion 40b.

The top surfaces of the gate electrode 40, the field plate electrode 50, and the conductive layer 60 of the MOSFET 200 are in a plane substantially parallel to the first face F1. The top surfaces of the gate electrode 40, the field plate electrode 50, and the conductive layer 60 of the MOSFET 200 are substantially in the same plane as the first face F1.

As shown in FIG. 14, the field plate electrode 50 is connected to the source electrode wiring 10x on the conductive layer 60 side of the end (Ex in FIG. 14) of the field plate insulating layer 55 in the first direction on the first face F1. In other words, the field plate electrode 50 is connected to the source electrode wiring 10x directly above the trench 31. The field plate electrode 50 is electrically connected to the source electrode wiring 10x using the field plate contact plug 10xa. The field plate contact plug 10xa is in contact with the field plate electrode 50.

The gate electrode 40 of the MOSFET 200 is electrically connected to the gate electrode wiring 12x using the gate contact plug 12xa. The gate contact plug 12xa is directly connected to the first portion 40a and the second portion 40b as shown in FIG. 16. The gate contact plug 12xa is in contact with the first portion 40a and the second portion 40b.

The MOSFET 200 can be manufactured, for example, by burying the field plate electrode 50, the conductive layer 60, and the gate electrode 40 in the trench 31 and then planarizing the surface of each electrode using a chemical mechanical polishing method (CMP method) or the like.

According to the MOSFET 200 of the second embodiment, since the gate capacitance is reduced, the speed of the MOSFET can be increased, as in the first embodiment. In addition, according to the MOSFET 200 of the second embodiment, for example, the depth of the opening when forming the field plate contact plug 10xa and the gate contact plug 12xa is the same. Therefore, the field plate contact plug 10xa and the gate contact plug 12xa can be easily formed.

### First Modification Example

A semiconductor device according to a first modification example of the second embodiment is different from the semiconductor device according to the second embodiment in that the conductive layer is electrically connected to the gate electrode.

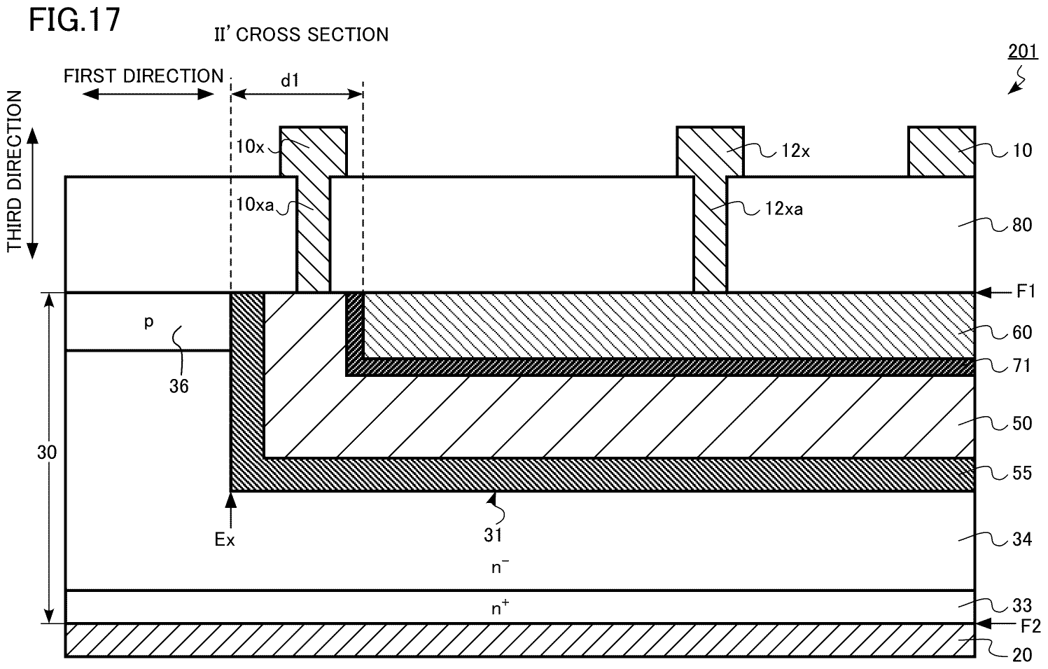

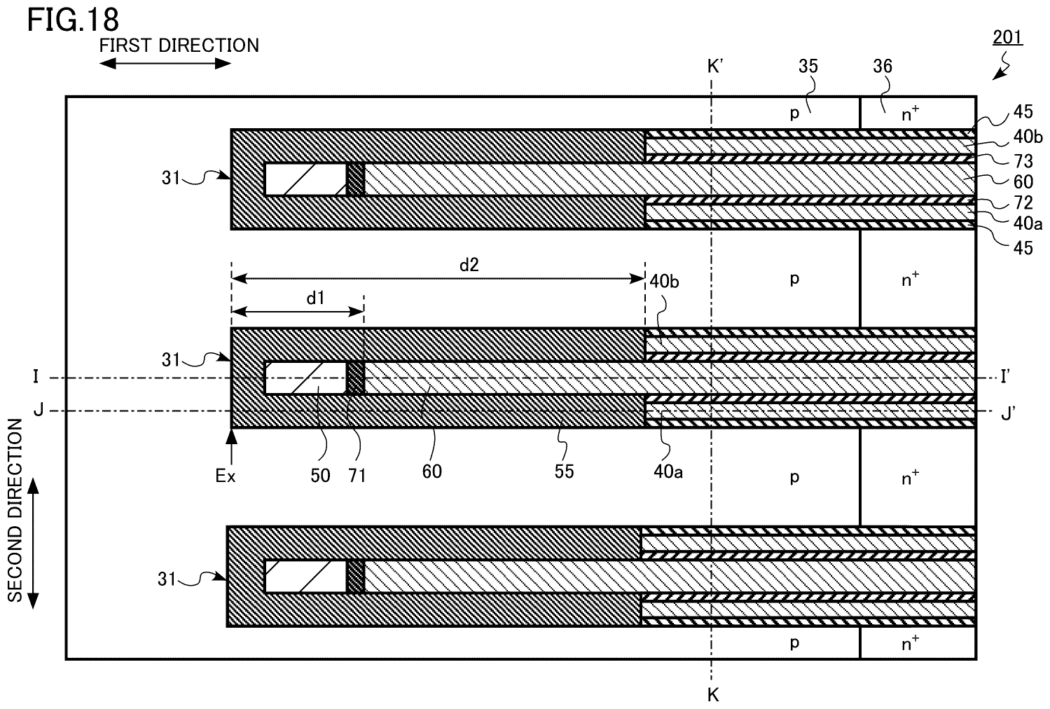

FIG. 17 is a schematic cross-sectional view of a part of the semiconductor device according to the first modification example of the second embodiment. FIG. 17 is a cross-sectional view taken along the line II′ of FIG. 18. FIG. 17 is a diagram corresponding to FIG. 14 in the second embodiment.

FIG. 18 is a schematic top view of a part of the semiconductor device according to the first modification example of the second embodiment. FIG. 18 is a diagram corresponding to FIG. 15 in the second embodiment.

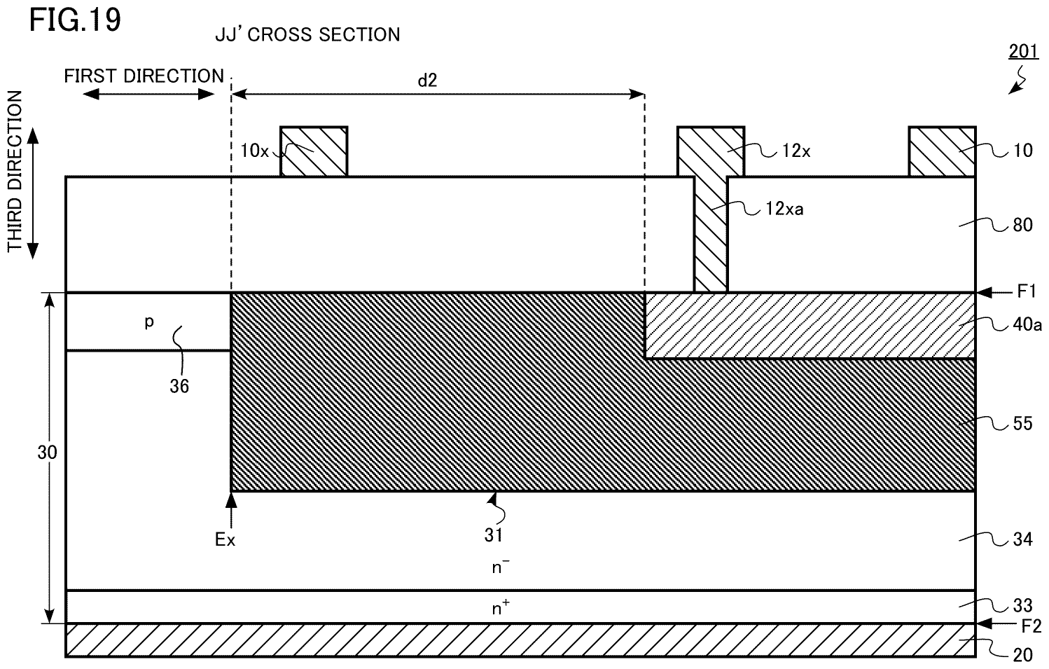

FIG. 19 is a schematic cross-sectional view of a part of the semiconductor device according to the first modification example of the second embodiment. FIG. 19 is a cross-sectional view taken along the line JJ′ of FIG. 18. FIG. 19 is a diagram corresponding to FIG. 16 in the second embodiment.

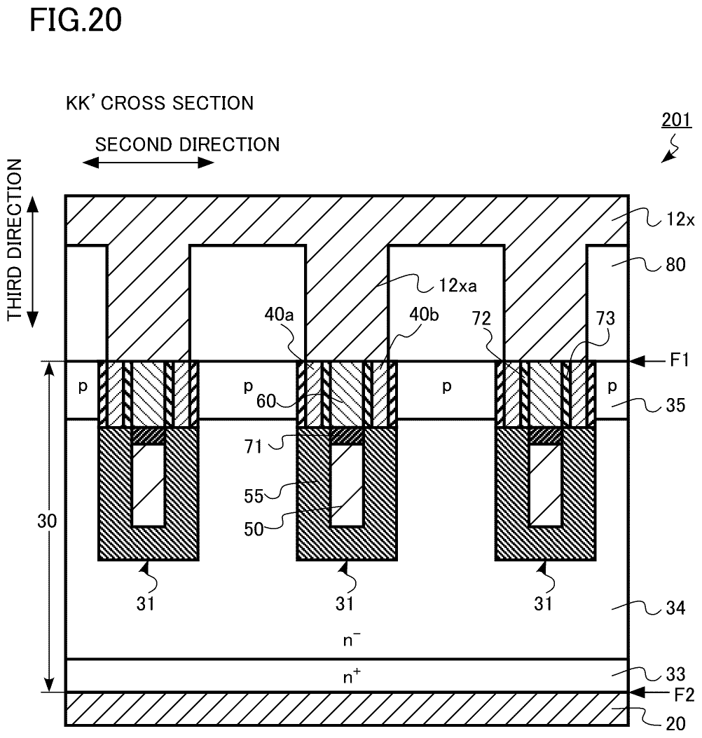

FIG. 20 is a schematic cross-sectional view of a part of the semiconductor device according to the first modification example of the second embodiment. FIG. 20 is a cross-sectional view taken along the KK′ of FIG. 18.

The semiconductor device according to the first modification example of the second embodiment is a MOSFET 201. In the MOSFET 201, as shown in FIG. 20, the gate contact plug 12xa is directly connected to the conductive layer 60 in addition to the first portion 40a and the second portion 40b. The conductive layer 60 is electrically connected to the gate electrode 40 by being electrically connected to the gate electrode wiring 12x. The conductive layer 60 is connected to the gate electrode wiring 12x using the same gate contact plug 12xa as the gate electrode 40.

Since the gate electrode 40 and the conductive layer 60 have the same potential, the gate capacitance does not increase even if the gate electrode 40 and the conductive layer 60 face each other in the second direction.

In the MOSFET 201 as well, the second distance d2 is larger than the first distance d1, as in the MOSFET 200 according to the second embodiment. Therefore, in the vicinity of the end Ex of the trench 31 in the first direction, the distance between the gate electrode 40 and the field plate electrode 50 in a plane parallel to the first face increases. Therefore, in the MOSFET 201 as well, the gate-source capacitance is reduced, similarly to the MOSFET 200 according to the second embodiment. As a result, since the gate capacitance of the MOSFET 201 is reduced, the speed of the MOSFET 201 can be increased.

In the MOSFET 201, since the conductive layer 60 has the same potential as the gate electrode 40, the capacitance between the conductive layer 60 and the field plate electrode 50 becomes the gate-source capacitance. The gate-source capacitance of the MOSFET 201 can be reduced, for example, by increasing the thickness of the first interelectrode insulating layer 71.

According to the MOSFET 201 of the first modification example of the second embodiment, since the gate capacitance is reduced, the speed of the MOSFET can be increased, as in the second embodiment.

### Second Modification Example

A semiconductor device according to a second modification example of the second embodiment is different from the semiconductor device according to the second embodiment in that the conductive layer is connected to the gate electrode wiring using a gate contact plug different from the gate electrode.

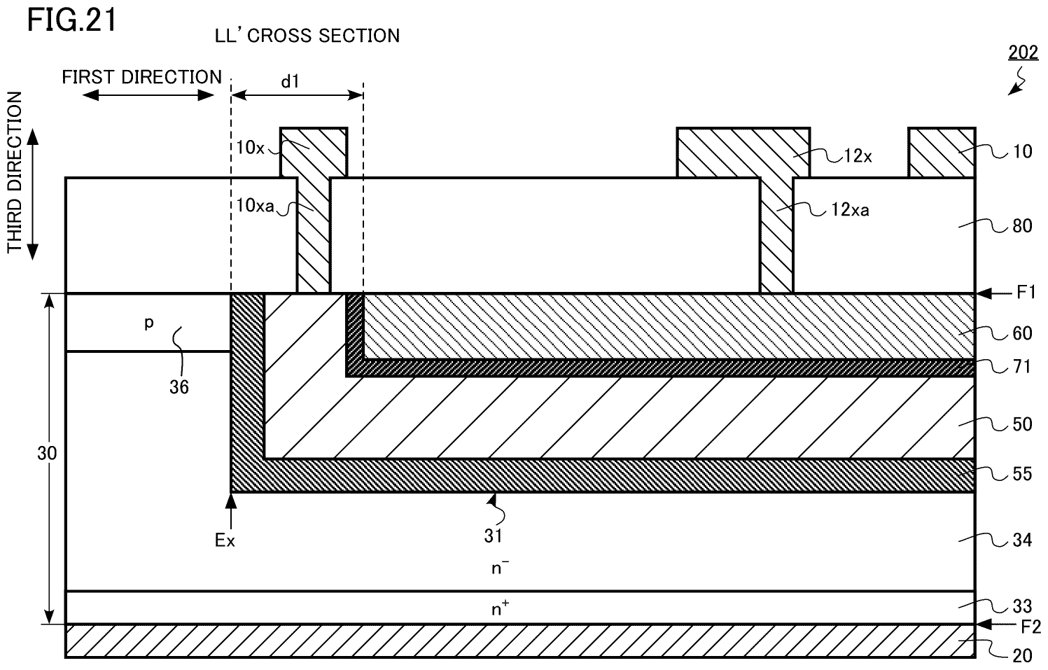

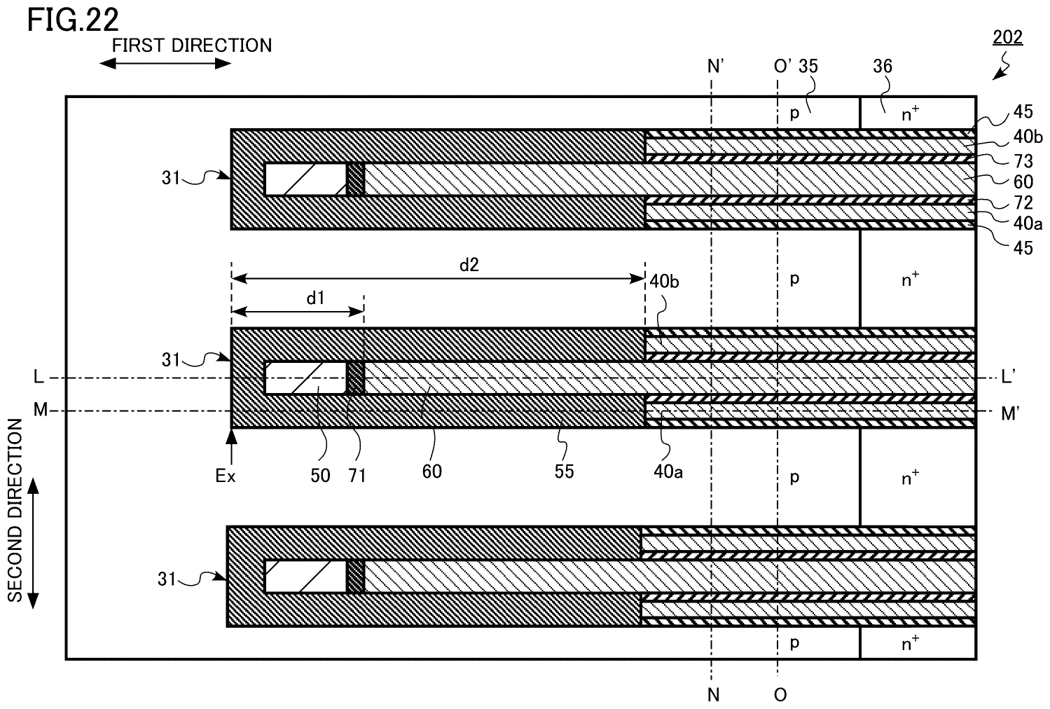

FIG. 21 is a schematic cross-sectional view of a part of the semiconductor device according to the second modification example of the second embodiment. FIG. 21 is a cross-sectional view taken along the line LL′ of FIG. 22. FIG. 21 is a diagram corresponding to FIG. 17 in the first modification example of the second embodiment.

FIG. 22 is a schematic top view of a part of the semiconductor device according to the second modification example of the second embodiment. FIG. 22 is a diagram corresponding to FIG. 18 in the first modification example of the second embodiment.

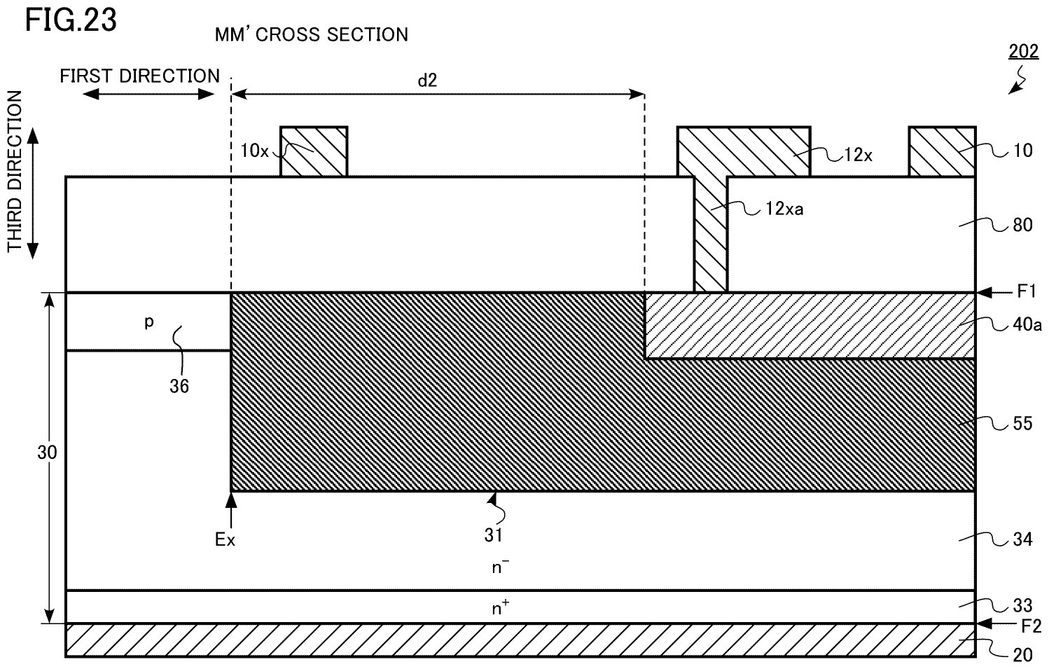

FIG. 23 is a schematic cross-sectional view of a part of the semiconductor device according to the second modification example of the second embodiment. FIG. 23 is a cross-sectional view taken along the line MM′ of FIG. 22. FIG. 23 is a diagram corresponding to FIG. 19 in the first modification example of the second embodiment.

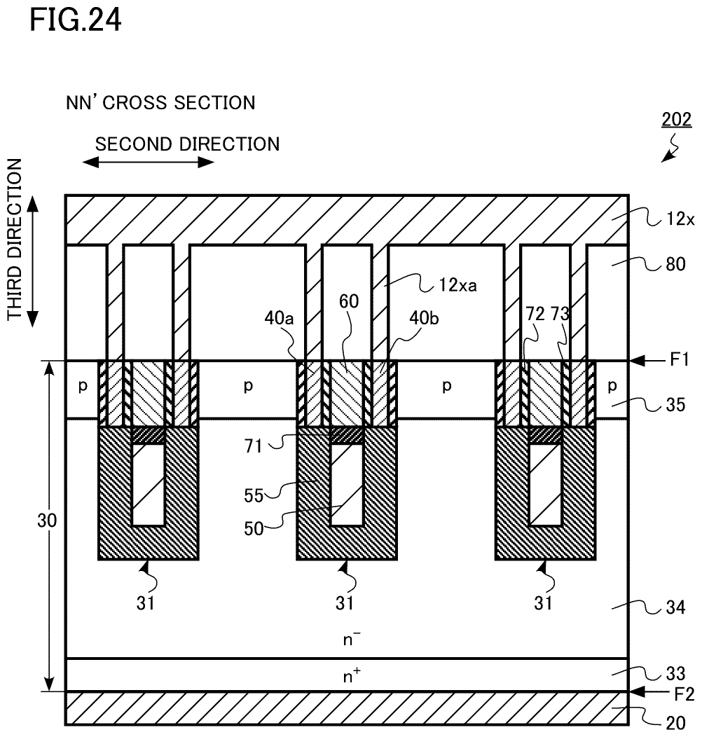

FIG. 24 is a schematic cross-sectional view of a part of the semiconductor device according to the second modification example of the second embodiment. FIG. 24 is a cross-sectional view taken along the line NN′ of FIG. 22. FIG. 24 is a diagram corresponding to FIG. 20 in the first modification example of the second embodiment.

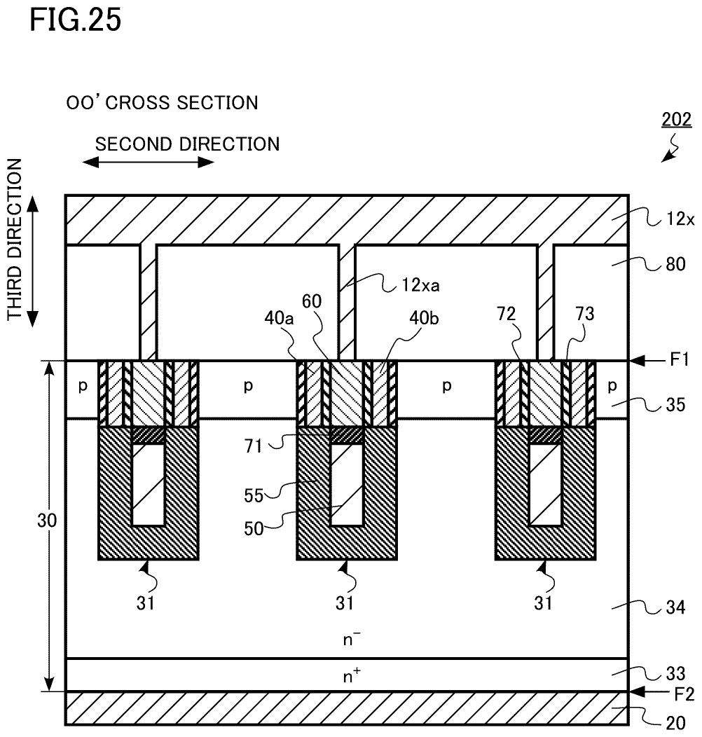

FIG. 25 is a schematic cross-sectional view of a part of the semiconductor device according to the second modification example of the second embodiment. FIG. 25 is a cross-sectional view taken along the line OO′ of FIG. 22.

The semiconductor device according to the second modification example of the second embodiment is a MOSFET 202. In the MOSFET 202, as shown in FIG. 24, the gate contact plug 12xa is directly connected to the first portion 40a and the second portion 40b. In addition, in the MOSFET 202, the gate contact plug 12xa is directly connected to the conductive layer 60 as shown in FIG. 25. The conductive layer 60 is connected to the gate electrode wiring 12x using the gate contact plug 12xa different from the gate electrode 40.

According to the MOSFET 202 of the second modification example of the second embodiment, since the gate capacitance is reduced, the speed of the MOSFET can be increased, as in the second embodiment.

In the embodiment, the case where the semiconductor layer is single crystal silicon has been described as an example. However, the semiconductor layer is not limited to the single crystal silicon. For example, other single crystal semiconductors, such as single crystal silicon carbide, may be used.

In the embodiment, the case where the first conductive type is n-type and the second conductive type is p-type has been described as an example. However, the first conductive type can be p-type and the second conductive type can be n-type.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
a semiconductor layer provided between the first electrode and the second electrode, having a first face facing the first electrode and a second face facing the second electrode, and including a first semiconductor region of a first conductive type electrically connected to the second electrode, a second semiconductor region of a second conductive type provided between the first semiconductor region and the first face, and a third semiconductor region of the first conductive type provided between the second semiconductor region and the first face and electrically connected to the first electrode;
a gate electrode including a first portion provided in the semiconductor layer and extending in a first direction parallel to the first face and a second portion disposed in a second direction parallel to the first face and perpendicular to the first direction with respect to the first portion;
a field plate electrode provided in the semiconductor layer, provided between the gate electrode and the second face, and electrically connected to the first electrode;
a conductive layer provided in the semiconductor layer, provided between the first portion and the second portion, and electrically separated from the first electrode;
a gate insulating layer provided between the gate electrode and the semiconductor layer;
a field plate insulating layer provided between the field plate electrode and the semiconductor layer;
a first insulating layer provided between the conductive layer and the field plate electrode;
a second insulating layer provided between the first portion and the conductive layer; and
a third insulating layer provided between the second portion and the conductive layer,
wherein a first distance in the first direction between an end of the field plate insulating layer in the first direction on the first face and the conductive layer is smaller than a second distance between the end and the gate electrode in the first direction.

2. The semiconductor device according to claim 1,
wherein the conductive layer is electrically separated from the gate electrode.

3. The semiconductor device according to claim 1,
wherein the conductive layer is floating.

4. The semiconductor device according to claim 1,
wherein the conductive layer is electrically connected to the gate electrode.

5. The semiconductor device according to claim 1,
wherein a difference between the second distance and the first distance is larger than a depth of the field plate insulating layer.

6. The semiconductor device according to claim 1,
wherein a difference between the second distance and the first distance is equal to or more than 10 μm.

7. The semiconductor device according to claim 1,
wherein a thickness of the first insulating layer between the conductive layer and the field plate electrode in a third direction perpendicular to the first direction and the second direction is larger than a thickness of the gate insulating layer in the second direction.

8. The semiconductor device according to claim 1,
wherein a thickness of the first insulating layer between the conductive layer and the field plate electrode in a third direction perpendicular to the first direction and the second direction is equal to or more than twice a thickness of the gate insulating layer in the second direction.

9. The semiconductor device according to claim 1,
wherein, at an end of the conductive layer in the first direction, an angle between an interface between the conductive layer and the first insulating layer and the first face is equal to or less than 60°.

10. The semiconductor device according to claim 1, further comprising:
a gate electrode pad provided on a first face side of the semiconductor layer;
a gate electrode wiring provided on the first face side of the semiconductor layer, extending in the second direction, connected to the gate electrode pad, and connected to the gate electrode; and
a source electrode wiring provided on the first face side of the semiconductor layer, extending in the second direction, connected to the first electrode, and connected to the field plate electrode,
wherein the gate electrode wiring is provided between the source electrode wiring and the first electrode in the first direction.

11. The semiconductor device according to claim 1, further comprising:
a gate electrode pad provided on a first face side of the semiconductor layer; and
a gate electrode wiring provided on the first face side of the semiconductor layer and connected to the gate electrode pad,
wherein the gate electrode further includes a third portion extending in the second direction and connecting the first portion and the second portion to each other, and
the gate electrode is connected to the gate electrode wiring directly above the third portion.

12. The semiconductor device according to claim 1, further comprising:
a source electrode wiring provided on a first face side of the semiconductor layer and connected to the first electrode,
wherein the field plate electrode is connected to the source electrode wiring on a side of the conductive layer of the end.
